(19) United States
(12) Patent Application Publication
(10) Pub. No.: US 2024/0346202 A1
(43) Pub. Date: Oct. 17, 2024

(54) METHODS AND SYSTEMS FOR POWER GRID OPTIMIZATION FOR CHARGING SYSTEMS OF ELECTRIC AIRCRAFT

(71) Applicant: Purdue Research Foundation, West Lafayette, IN (US)

(72) Inventors: Seejay Romello Patel, Denver, CO (US); Nicholas Ilham Gunady, West Lafayette, IN (US); Keshav Rajesha Iyengar, West Lafayette, IN (US); Austin LU, West Lafayette, IN (US)

(73) Assignee: Purdue Research Foundation, West Lafayette, IN (US)

(21) Appl. No.: 18/637,259

(22) Filed: Apr. 16, 2024

Related U.S. Application Data
(60) Provisional application No. 63/459,976, filed on Apr. 17, 2023.

(51) Int. Cl. G06F 30/18

(52) U.S. Cl. CPC G06F 30/18

(57) ABSTRACT

A method of optimizing an Urban air mobility (UAM) network is disclosed which includes receiving a predetermined vertiport network, wherein each vertiport in the predetermined network is represented by a plurality of parameters, receiving a customer demand schedule representing customer demand for each said vertiport, using a model simulating the UAM network thus outputting a solution for the plurality of parameters, inputting the output of the simulation to a genetic algorithm (GA), optimizing the GA to thereby generate an optimized solution based on minimizing a mathematical function associated with the plurality of parameters until a predetermined termination criteria associated with network size is reached, and outputting the optimized solution.

### CROSS-REFERENCE TO RELATED APPLICATIONS

The present non-provisional patent application is related to and claims the priority benefit of U.S. Provisional Patent Application Ser. 63/459,976, filed Apr. 17, 2023, the contents of which are hereby incorporated by reference in its entirety into the present disclosure.

### STATEMENT REGARDING GOVERNMENT FUNDING

None.

### TECHNICAL FIELD

The present disclosure is generally related to power grids, and in particular to optimizing electrical infrastructure associated with charging electric aircrafts.

### BACKGROUND

This section introduces aspects that may help facilitate a better understanding of the disclosure. Accordingly, these statements are to be read in this light and are not to be understood as admissions about what is or is not prior art.

With the advent of aerial drones, there has been a significant amount of interest directed to Urban air mobility (UAM) leading to a multimodal infrastructure for urban settings. Generally, UAM refers to a system of relatively small aircrafts that can move cargo and passengers by landing and taking off from vertiports. Such a system holds the promise of reducing on-ground traffic congestion and speed up traffic through the airspace above an urban or a suburban area. Typically, the type of aircrafts considered for a UAM system include vertical-takeoff-and-landing aircraft (VTOL) that are based on gas or electric propulsion which include manned or unmanned aerial vehicles (UAVs). In particular, over 300 different electric VTOL (eVTOL) vehicles are in development today, employing advances in technology, including electric propulsion, automation, and materials science. These advances are enabling the design of aircraft that are quieter, and more efficient than traditional fuel-burning aircraft. Advanced air mobility (AAM) has garnered significant attention from major industry players such as UBER, BOEING, and NASA, all of which have released white papers outlining their visions for the future of advanced air transportation. Widespread implementation of AAM has the potential to alleviate congestion, reduce emissions, and improve accessibility in urban areas, as well as to connect underserved regions and communities.

To accommodate a UAM network, vertiports are needed to allow vertical landing and takeoff of VTOLs. More generally, a vertiport is a term used to describe the specialized ground facility designed to serve as a base for UAM operations, including features such as landing pads, charging stations, and passenger amenities. These structures may be located on the ground or on rooftops and will need to be carefully designed to support the unique landing and takeoff requirements of UAM aircraft. An AAM Infrastructure Readiness (AIR) Index has been developed which assesses the readiness of AAM infrastructure companies towards the deployment of commercial operations worldwide. The AIR Index indicates that UAM networks which include vertiports are being considered for construction in at-grade market locations, multi-story parking garages, and high-rise buildings.

A passenger-carrying UAM network primarily encompasses two major use cases within the transportation system: air-metro and air-taxi. The air-metro use case aims to offer transportation services on a scheduled basis, similar to the operations of subway and metro trains that follow set schedules. Two comprehensive studies commissioned by NASA suggest that air-metro operations are likely to precede on-demand air-taxi implementations due to the lower infrastructure requirements. One key advantage of the air-metro use case is its facilitation of scheduled UAM departures, which streamlines airspace reservation and simplifies autonomous operations. WISK, a BOEING-funded UAM company, has already committed to adopting the air-metro operation model for its UAM vehicle. In addition to passenger transportation, air-metro services also encompass cargo delivery within urban areas. This approach enables companies to swiftly and efficiently transport goods between distribution centers, thereby reducing delivery times and costs, as well as decreasing the number of heavy-duty trucks on the road.

Thus, while a UAM systems have the potential to revolutionize the transportation industry, offering fast, convenient, and sustainable travel options for passengers and cargo. The development and operation of UAM networks, however, face significant challenges, including the need for infrastructure investments and the management of grid electricity usage.

Therefore, there is an unmet need for a novel comprehensive model of UAM network operations as related to grid electricity usage which can employ a data-driven simulation framework to analyze the expected performance of a UAM operation.

### SUMMARY

A method of optimizing an Urban air mobility (UAM) network is disclosed which includes receiving a predetermined vertiport network, wherein each vertiport in the predetermined network is represented by a plurality of parameters, receiving a customer demand schedule representing customer demand for each said vertiport, using a model simulating the UAM network thus outputting a solution for the plurality of parameters, inputting the output of the simulation to a genetic algorithm (GA), optimizing the GA to thereby generate an optimized solution based on minimizing a mathematical function associated with the plurality of parameters until a predetermined termination criteria associated with network size is reached, and outputting the optimized solution.

A system of optimizing an Urban air mobility (UAM) network is also disclosed which includes a UAM network. The UAM network includes a vertiport network of a plurality of vertiports, each vertiport defined by a plurality of parameters, an electric grid coupled to the vertiport network, and a processor executing instructions on a non-transitory memory. The processor is configured to receive a predetermined vertiport network, wherein each vertiport in the predetermined network is represented by the plurality of parameters, receive a customer demand schedule representing customer demand for each said vertiport, simulate the UAM network using a model thus outputting a solution for the plurality of parameters, input the output of the simulation to a genetic algorithm (GA), optimize the GA to thereby generate an optimized solution based on minimizing a mathematical function associated with the plurality of parameters until a predetermined termination criteria associated with network size is reached; and output the optimized solution.

### BRIEF DESCRIPTION OF FIGURES

FIG. 1 is a schematic that describes six levels of Urban air mobility (UAM) maturity level (UML) scale which are distinguished by three primary attributes: traffic density, operational complexity, and reliance on automation.

FIG. 2A is a flow diagram depicting simulation environment at different levels including Alpha (α): passengers, vehicles, battery, grid, solar panels, and charger; Beta (β): fleet, demand, energy system, and controller; Gamma (γ): vertiports; and Delta (δ): vertiport network, in which the simulation generates an output based on number of vehicles, batteries, solar panels, and chargers given a vertiport network and a passenger demand as input.

FIG. 2B is a block diagram according to the present disclosure including a genetic algorithm (GA) and a recursive use of the simulation environment shown in FIG. 2B which is used to optimize the UAM network, in which output is energy usage from the grid, number of vehicles, and stored energy based on number of batteries.

FIG. 3 is a block diagram of elements within the GA of FIG. 2B.

FIG. 4 is a chart showing results of convergence verification based on different maturity levels of UAM networks.

FIG. 5 is a bar chart showing results of an optimized UAM network for a first urban setting and for a first maturity level, in which an optimized output (i.e., number of vehicles, charger, solar panels, and batteries) are provided for each vertiport (based on the order: number of vehicles at the bottom, number of chargers, number of solar panels, and number of batteries, where if solar panels and batteries are coupled such that if there are no solar panels there are no batteries).

FIG. 6 is another bar chart similar to FIG. 5 showing results of an optimized UAM network for the first urban setting and for a second maturity level.

FIG. 7 is another bar chart similar to FIG. 5 showing results of an optimized UAM network for the first urban setting and for a third maturity level.

FIG. 8 is another bar chart similar to FIG. 5 showing results of an optimized UAM network for a second urban setting and for the first maturity level.

FIG. 9 is another bar chart similar to FIG. 5 showing results of an optimized UAM network for the second urban setting and for the second maturity level.

FIG. 10 is another bar chart similar to FIG. 5 showing results of an optimized UAM network for the second urban setting and for the third maturity level.

FIG. 11 provides three graphs of i) energy in kW (for both solar panels and power requested from the grid); ii) number of chargers; and iii) stored energy (i.e., state of charge of all batteries), the graphs are for one of the vertiports in an urban setting, and vs. timestep defining length of a day.

FIG. 12 provides an average of grid demand and cost for all vertiport in the urban setting of FIG. 11.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel comprehensive model of operations of an Urban air mobility (UAM) network as related to grid electricity usage is disclosed herein. Towards this end, a data-driven simulation framework is described that can analyze the expected performance of a UAM operation.

The approach described herein, optimizes the composition of the UAM network, including the number of vehicles, chargers, and sizing of solar microgrids, to minimize total acquisition costs while adhering to operational constraints such as maximum average passenger delay and grid usage for each vertiport. This approach described herein contributes to the development of sustainable and efficient UAM systems, supporting informed decision-making among stakeholders involved in the planning, deployment, and operation of urban air mobility networks.

The present disclosure primarily focuses on the air-taxi use case, which involves the utilization of UAM vehicles for on-demand mobility (ODM) of passengers and goods. Similar to popular rideshare applications such as UBER or LYFT, ODM enables passengers, their cargo, or cargo alone, to book UAM flights through their smartphones or other devices while tracking their flights' statuses in real-time. This modality offers a flexible and convenient mode of transportation, allowing individuals to schedule flights on-demand rather than planning trips in advance. The air-taxi use case exemplifies how UAM can revolutionize the movement of people and goods within and between cities, fostering new forms of commerce and services.

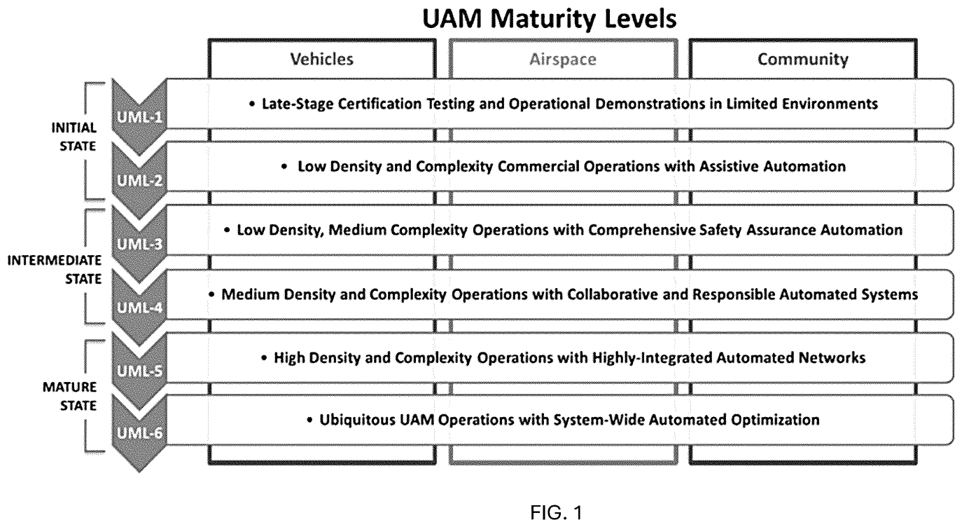

To address some of the key challenges and opportunities of UAM, NASA has devised a framework known as the UAM maturity level (UML) scale. The UML scale categorizes the critical phases of a UAM transportation system's evolution, ranging from its current state to a highly advanced future state where UAM is a widely accessible capability. Referring to FIG. 1, a schematic is provided that describes six levels of the UML scale which are distinguished by three primary attributes: traffic density, operational complexity, and reliance on automation for the vehicles, airspace, and the community dividing the UML scale in to six three phases: an initial state, an intermediate state, and a mature state.

One aspect of a vertiport is the electrical charging of vertical takeoff and landing (VTOL) vehicles. Since electric aircraft depend on electricity for propulsion and require charging between flights, vertiports need to incorporate charging infrastructure connected to the electrical grids and might also connect to renewable energy sources such as solar panels, electrical wind mills, battery storage networks, wave power generation systems, and other renewable energy systems known to a person having ordinary skill in the art.

Thus, a UAM network requires developing specialized infrastructure, such as vertiports, charging stations at extremely fast charging rates (e.g., 600 kW), and landing pads, and integrating these elements into an overall network to support UAM aircraft operation. Careful consideration of vertiport sizing and placement is essential to ensure that the network can effectively meet passenger demand while minimizing operational costs and environmental impact. These rapid charging rates will undoubtably place considerable strain on local electric grids. Specifically, in recent years, the U.S. electric grid has faced limitations, as demonstrated by events that are typically weather related including the necessity for rolling blackouts. Thus, vertiport deign topologies need to employ smart grid management strategies including both the existing electric grid and vertiport-attached renewable energy sources to ensure long-term sustainability and efficient UAM operations.

Such renewable sources include a variety of different energy sources. For example, solar microgrids include solar panels, energy storage systems, and a control system. They generate electricity from sunlight and store excess energy in batteries for later use, reducing the dependency on the local electric grid. The sizing of solar generation and energy storage systems is critical for ensuring that the microgrid can meet the vertiport's energy needs during peak and off-peak times. This involves determining the optimal number of solar panels, battery capacity, and the required power output for the microgrid. Proper sizing of the solar microgrid helps in achieving a balance between investment costs, operational costs, and energy reliability, leading to sustainable and efficient UAM operations.

The present disclosure provides a methodology by which placement and size of vertiports in a UAM network is optimized. Placement includes identifying the real estate location for a vertiport, while sizing encompasses determining the necessary infrastructure to support the vertiport operation. This sizing may include determining the number of landing pads, the dimensions of the passenger terminal space, the acquisition of on-site power generation and energy storage, and other investments. The optimization of these factors is crucial for ensuring sustainability of a UAM vertiport network.

To meet the energy demands of vertiports, a solar microgrid, which combines solar power and on-site battery storage, can be employed. This solution not only guarantees a consistent power supply but also lessens dependence on the local electric grid and contributes to a reduced carbon footprint. Solar energy is an appealing option for microgrids due to its widespread availability, eco-friendly nature, decreasing solar panel costs, and demonstrated success, as evidenced by its implementation at large airports. Furthermore, solar energy generation can be tailored to the size of the vertiport, offering design flexibility for the solar microgrid.

On-site battery storage captures surplus energy produced by solar panels during periods of peak sunlight, ensuring a continuous power supply during low sunlight hours or nighttime. This allows vertiports to operate around the clock, even without grid power. In addition, battery storage systems can supply power during peak demand periods when the grid may face high stress, thereby alleviating pressure on the local electric grid and preventing potential blackouts.

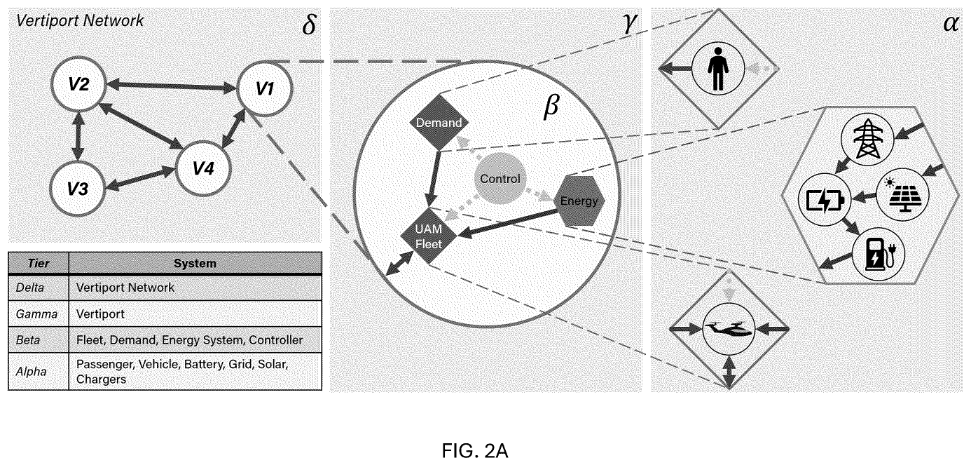

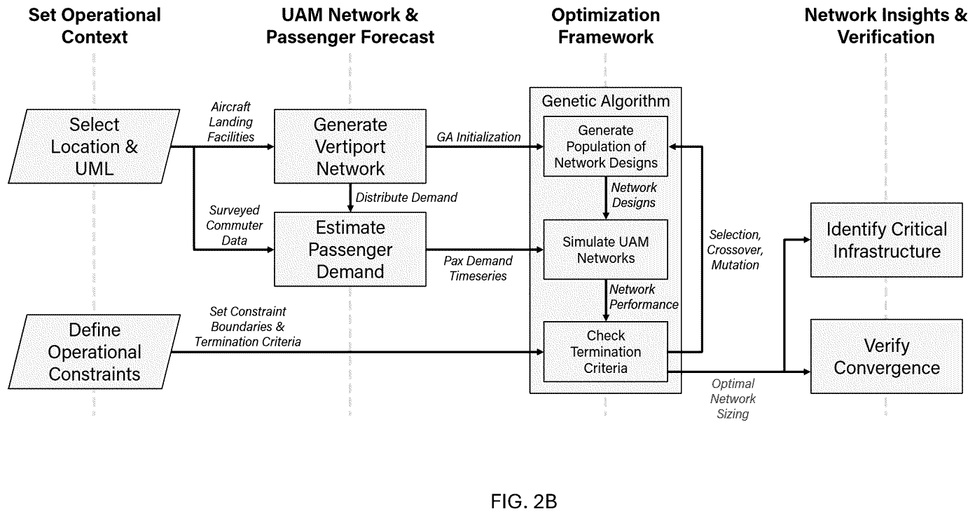

Referring to FIG. 2A a flow diagram is provided which depicts a simulation environment at different levels including Alpha (α): passengers, vehicles, battery, grid, solar panels, and charger; Beta (β): fleet, demand, energy system, and controller; Gamma (γ): vertiports; and Delta (δ): vertiport network, in which the simulation generates an output based on number of vehicles, batteries, solar panels, and chargers given a vertiport network and a passenger demand as input. Thus from a system view, the simulation framework receives as inputs passenger demand, a predetermined vertiport design including a predetermined number of vertiports each with a longitude and latitude coordinate, and provides as output for the UAM network (i.e., for each vertiport of the predetermined vertiport network) the needed number of vehicles, charging station, solar panels, batteries. Solar panels and batteries are coupled to each other, meaning if there is at least one solar panel at a vertiport, there is at least one battery; but if there are no solar panels at a vertiport, there would be no batteries at that vertiport.

Referring to FIG. 2B, a block diagram is provided to depict the process to identify the optimal UAM Network Composition, according to the present disclosure. In particular, FIG. 2B illustrates the overall process for UAM network modeling and optimization, according to the present disclosure, which is divided into four major steps: Set operational context, UAM Network & Passenger forecast, optimization framework, and network insights & verification.

The process shown in FIG. 2B has two main components: 1) a simulation component shown in FIG. 2A and an optimization component carried out by a genetic algorithm (GA) in a recursive fashion using the simulation output as its inputs until a steady state solution is achieved based on a termination criterion. The output of the GA is the optimized network sizing which includes number of vehicles, chargers, solar panels, and batteries, first for each vertiport and secondly an average across all vertiports. The vertiport network design is an input to the process shown in FIG. 2B based on a predetermined design stemming from passenger demand. The optimization performed by the GA is based on minimizing the relationship 3a, provided below and the conditions set forth in relationships 3b-3g. The genetic algorithm determines that it has converged to a solution based on termination criteria. The termination criteria represent selectable criteria based on needs of the UAM network. According to one embodiment, the termination criteria will stop the optimization process when the same optimal design is selected for a predetermined number of populations, e.g., 15, in a row. This approach helps to prevent the GA from running indefinitely while ensuring that the solution has remained consistent across multiple generations.

According to another embodiment, the termination criteria also require that the rest of the population is within the tolerance of the selected network design, combining elements of fitness convergence and population convergence. This condition ensures that the fitness of the solutions has reached an acceptable level of consistency, and the population has converged, minimizing the likelihood of a suboptimal outcome

This process accomplishes the goal of UAM network modeling and optimization by developing a simulation of UAM operations at the network level. The simulation models various interactions between systems and subsystems, including vertiports, the UAM fleet, passengers, and energy systems. The outcomes of these simulations enable us to identify key performance metrics such as passenger wait times, energy usage, and carbon emissions. These metrics serve as the basis for evaluating the sustainability and efficiency of different UAM network configurations. Subsequently, the simulation is integrated into an optimization framework using the Genetic Algorithm (GA) to determine the optimal investment and composition for a vertiport network. The simulation is incorporated into an optimization framework that utilizes the GA, developed independently for the present disclosure, to determine the optimal investment and composition for a vertiport network.

The optimization process includes identifying four major subsystems related to: 1) the vertiport, 2) the vertiport energy system, 3) the UAM fleet, and 4) the passengers. These independent systems and their subsystems play a crucial role in the overall operation of UAM networks, and their interactions and dependencies are essential to consider when modeling UAM operations at the network level.

These 4 subsystems interact to establish the fleet of UAM vehicles, passenger demand, and the vertiport energy subsystem. For the purposes of this model, we define a vertiport as the location of ground-based infrastructure for UAM vehicles, including touchdown and lift-off (TLOF) zones, aircraft parking and long term storage, terminals for passenger loading and unloading, and any energy systems used to charge aircraft and power ground systems.

The model and simulation discussed herein, emulate the real-time operation of a UAM network over a full day of simulated operations, capturing the dynamic nature of passenger demand and energy usage throughout the day. In this simulation, passengers request trips from their origin vertiport, and their wait time is tracked to model the on-demand mobility ConOps. The tracking of passenger wait time is a critical performance metric as it directly affects the overall efficiency, user satisfaction, and economic viability of the UAM network.

The number of vehicles and chargers stationed at each vertiport plays a significant role in affecting passenger wait times. If a vertiport has insufficient number of vehicles or charging infrastructure, passengers may experience longer wait times due to the unavailability of adequately charged vehicles. This can lead to costly delays, negatively impacting the overall performance of the UAM network. Extended wait times not only decrease user satisfaction but can also have financial consequences for UAM operators, as they may result in lost revenue and increased operating costs.

During the course of the simulated day, the energy required for the UAM vehicle chargers is sourced from the local electric grid or, when available, from an on-site microgrid. The microgrid includes an on-site battery storage system and solar arrays, which provide a renewable energy source for the vertiport. The on-site battery serves as the primary source of electricity for the chargers if there is sufficient charge remaining. If the battery charge is depleted, the energy demand is met by drawing electricity from the local grid.

While the above-four critical parameters/subsystems (i.e., 1) the vertiport, 2) the vertiport energy system, 3) the UAM fleet, and 4) the passengers), many other parameters that can affect the operation of the UAM network are not considered including: Weather and other environmental effects are not modeled, thus assuming ideal operating conditions for UAM vehicles; Solar generation is based on locational solar attitude and is not affected by weather and other stochastic effects, such as cloud cover; All energy consumption is driven by the charging of UAM vehicles, thus buildings electrical needs and other vehicle charging are not modeled; vehicles travel along predetermined paths to their destinations, without encountering stochastic delays or requiring rerouting due to traffic or other unforeseen events; vehicles are fully charged before being dispatched to ensure adequate power for the entire trip; vehicles are charged at a 6C rate, which implies that a full charge will be achieved in 10 minutes; fleet operators initiate a dead-head trip, or a trip without passengers, back to the vertiport of origin once a passenger is delivered to their destination; vehicles service one passenger per trip, assuming no shared rides or multiple stops; all trips are on-demand and passenger wait time is calculated from the timestep when a passenger requests the trip to the moment the vehicle is ready for takeoff; passengers do not experience stochastic events such as canceled trips, late arrivals, or other disruptions to the trip schedule; passenger trips are serviced on a “first come, first served” basis, ensuring fairness in allocating UAM vehicles to passengers; and passenger demand patterns are based on local commuter data and distributions.

UAM vehicles specification such as weight, thrust, and power consumption are obtained from a known UAM vehicle dataset. This data was then incorporated into the simulation to provide a more accurate representation of the UAM fleet's power usage during flight. Equation 1 describes the power required for a UAM vehicle in cruise:

$${P}_{c r u i s e} = \frac{m g}{\frac{L}{D}} \frac{V}{{η}_{c}} \qquad ( 1 )$$

where P_{cruise} represents the power consumption during cruise,
m is the vehicle's mass,
g is the acceleration due to gravity,
L/D is the lift to drag ratio,
V is the vehicle's velocity, and
η_{c} is the propulsion efficiency.

Equation 1 allows the simulation environment to predict the power consumption of the UAM trips and, in turn, the charging requirements of the vertiport energy system to meet the needs of the UAM fleet. The vehicle dynamics during takeoff, landing, climb, and descent are not considered in the simulation. These stages of flight are typically much shorter in duration and were found to have a relatively small impact on the overall energy consumption of a UAM flight.

To forecast passenger demand for a given vertiport network, an existing database (Longitudinal Employer-Household Dynamics (LEHD) Origin-Destination Employment Statistics (LODES) commuter dataset) was used. LODES offers an extensive range of commuter-related statistics, with the simulation of the present disclosure specifically targeting origin and destination data to estimate the relative demand for each vertiport. This method allows for an assessment of the vertiport network's potential usage based on urban commuter patterns.

Using the LODES dataset and the described sampling methodology allows us to forecast passenger demand at a granular level, enabling more precise planning and optimization of the vertiport network.

To estimate the potential demand at each vertiport, a known database (the metropolitan CoreBased Statistical Area (CBSA)) is used along with identifying census tracts within a 15-mile radius of each vertiport. This process enables the estimation of the number of commuters likely to utilize a vertiport network to provide transportation from their origin to their destination. Subsequently, we apply a binomial distribution to the sampled demand to represent traditional metropolitan rush hour times. By examining this distribution, we can effectively estimate vertiport origin and destination as well as the time of trip requests.

Solar energy generation for UAM vertiports is simulated using Pysolar, a PYTHON library for estimating the clear sky solar radiation hitting the earth's surface at any given location. This library is based on precise ephemeris calculations and does not consider weather or other stochastic effects. Equation 2 is used to calculate the instantaneous solar power generated, Pₛₒₗₐᵣ:

$${P}_{solar} = Q A {η}_{s} \qquad ( 2 )$$

where Q is the solar irradiance hitting the earth's surface in Watts per square meter,
A is the total solar farm area (m²), and
ηₛ is the solar panel efficiency for converting irradiance to usable electricity. Most commercial
PV panels have efficiencies ranging from 15% to 20%, but researchers have developed PV cells with efficiencies approaching 50%.

Three key performance metrics are calculated as outputs of the UAM network simulation: total grid energy usage, average passenger delay, and carbon emissions. The total grid energy usage is calculated by summing the cumulative energy used by each vertiport to charge vehicles during the simulation. Average passenger delay is determined by calculating the waiting time for each passenger before their UAM vehicle is ready to complete their trip. Total carbon emissions of the network are calculated after the simulation is complete, based on the relative carbon index for the network location and the amount of grid energy used during the simulation. A similar process is used by prior art to calculate the estimated carbon emissions of various AAM missions. These outcomes provide insight into the expected sustainability and efficiency of the UAM network and can be used to inform investment and operational decisions.

The optimization process of the present disclosure involves using the simulation described above as a function to evaluate the expected performance of different configurations of vehicle fleet size, number of chargers, and on-site solar area for each vertiport in the UAM network. The genetic algorithm iteratively improves the configuration of the UAM network, considering the various trade-offs between investment costs and operational performance, until an optimal solution, or set of equivalent solutions, is found. The results of this optimization provides valuable insights for decision-makers considering the investment in UAM vertiports. FIG. 2B illustrates the implemented process of identifying an optimal UAM network composition.

The optimization framework begins by inputting the location where a UAM network will be analyzed and the desired UML of the operation. This information is used to identify the number of vertiports in the network and their locations. These inputs are then used to generate passenger demand for the network. Operational constraints and termination criteria are inputted and used by the GA to determine the optimal network sizing. The results of the GA are verified for convergence before the identified optimal network is accepted as the final result.

The scope of this formulation is aimed at evaluating the collaboration and acquisition between vertiport and fleet operators in the UAM ecosystem. In this context, vertiport operators need to determine the optimal size of vertiport stationing and charging capacity (vehicles and chargers), while fleet operators must establish the required number of vehicles to maintain a seamless operation.

The optimization formulation is detailed in equations 3a-3g:

$$minimize {\sum }_{v ∈ N} {C}_{u} {X}_{v u} + {C}_{c} {X}_{vc} + {C}_{s} {X}_{v s} + {C}_{b} {X}_{v b} \qquad ( 3 a )$$

$$Subject to : {PD}_{v} \leq P {D}_{max} ( {∀}_{v} ∈ N ) \qquad ( 3 b )$$

$$G {U}_{v} \leq G {U}_{max} ( {∀}_{v} ∈ N ) \qquad ( 3 c )$$

$$G {M}_{v} \leq G {M}_{max} ( {∀}_{v} ∈ N ) \qquad ( 3 d )$$

$$S {W}_{v} \leq S {W}_{max} ( {∀}_{v} ∈ N ) \qquad ( 3 e )$$

$${X}_{u v} , {X}_{c v} , {X}_{s v} , {X}_{b v} \geq 0 ( {∀}_{v} ∈ N ) \qquad ( 3 f )$$

$${X}_{u v} , {X}_{c v} , {X}_{s v} , {X}_{b v} ∈ Z ( {∀}_{v} ∈ N ) \qquad ( 3 g )$$

The optimization formulation aims to minimize the total network investment in USD ($), represented by the sum of the acquisition costs for vehicles (Cᵤ), chargers (C_{c}), and solar panels (Cₛ). Each vertiport, v, in the network, N, has four decision variables Xᵥᵤ, X_{vc}, Xᵥₛ, and X_{vb}. These decision variables represent the number of vehicles, chargers, solar area, and on-site battery size acquired for each vertiport (v). The optimization is subject to constraints on the maximum allowed average passenger delay (min), PDₘₐₓ, grid energy usage (kWh), GUₘₐₓ, grid demand peak (kW), GMᵥ, and solar wasted (kWh) due to full batteries, SWᵥ, at each vertiport. The decision variables must also be non-negative and are required to be integers. These constraints ensure that the solution for the optimization problem is feasible and practical for UAM implementation.

The genetic algorithm (GA) is a heuristic optimization method built on a plurality of generations where the best solutions have a higher probability of reproducing and passing on their traits to the next generation. GA formulations have been used in transportation system research to optimize many complex problems like scheduling, routing, and timing. In the present disclosure the GA is used to optimize the allocation of UAM infrastructure in a vertiport network to minimize total network investment while meeting operational requirements.

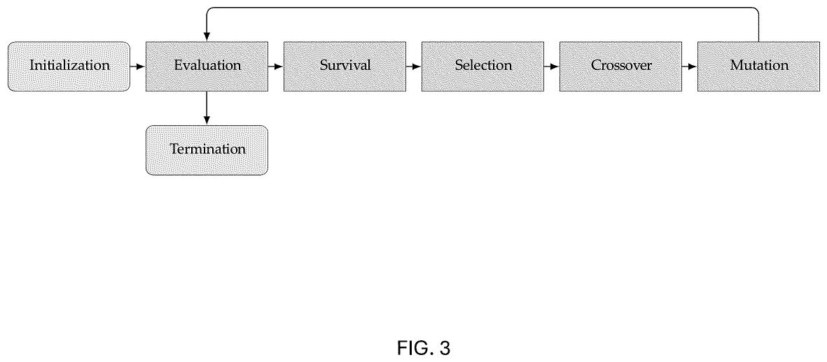

Referring to FIG. 3, a block diagram is shown which provides seven steps in the GA, according to the present disclosure, using PYTHON library Pymoo. The seven steps are (1) initialization of the population, (2) evaluation of fitness, (3) selection of parents, (4) crossover, (5) mutation, (6) evaluation of new population, and (7) termination or continuation of the process. The GA starts with a population of randomly generated vertiport network compositions and iteratively applies genetic operators such as crossover and mutation to generate new offspring. The performance of the offspring is then evaluated using the simulation, and the fittest individuals are selected to be included in the next generation. This process continues until the GA converges to a satisfactory solution.

A simple example of the execution of the GA based on Pymoo is shown in the pseudocode below:

```
from pymoo.algorithms.soo.nonconvex.ga import GA
from pymoo.problems import get_problem
from pymoo.optimize import minimize
problem = get_problem(“g1”)
algorithm = GA(
  pop_size=100,
  eliminate_duplicates=True)
res = minimize(problem,
    algorithm,
    seed=1,
    verbose=False)
print(“Best solution found: \nX = %s\nF = %s” % (res.X, res.F))
```

Two case studies were undertaken, one in Los Angeles, CA and one in Chicago, IL. These cities were chosen as case studies for several reasons. First, both locations are large metropolitan areas where UAM companies are actively investing in infrastructure, indicating a strong potential for UAM growth in the coming years. Secondly, The geographical differences between Los Angeles and Chicago, particularly in terms of latitude, result in significant variations in solar radiation, which can impact the energy dynamics and sustainability of UAM operations.

To initiate each case study, we first establish the context of UAM operations in each city. This includes the vertiport network, passenger demand, required vertiport performance, and the acquisition costs associated with each asset.

The optimization formulation seeks to minimize the acquisition costs associated with the key components of the UAM network. Table 1 presents these individual costs, including the tiltrotor UAM vehicle, a 600 kW EV charger, solar PV generation, and on-site solar batteries. Given the proprietary nature of information regarding UAM vehicles and chargers, we rely on available sources and trade studies to provide reasonable estimates.

TABLE 1
Acquisition Cost Values used in these Case Studies

| Modeled System | Unit Cost |
|---|---|
| Tiltrotor UAM Vehicle | $ X1 |
| 600 kW EV Charger | $ X2 |
| Solar PV (per 500 m²) | $ X3 |
| On-site Battery (per 100 kWh) | $ X4 |

The constraints described above define the performance metrics for each vertiport in a network. For these case studies, we set the maximum passenger wait time to 30 minutes, taking into consideration passenger satisfaction and time savings for transportation services. The maximum electricity grid demand is constrained by local infrastructure. We also set the grid maximum constraint at 5000 kW to prevent incurring surcharge costs. A grid usage constraint of 6000 kWh was chosen, taking into account various factors such as operating costs, grid restrictions, local regulations, and grid capacity limitations. This constraint aims to strike a balance between utilizing grid-supplied electricity and maintaining a stable and reliable grid connection for the vertiport network.

To ensure optimal microgrid sizing and avoid the generation of excess solar power that cannot be stored, we have constrained solar waste to 0 kWh. This measure is important for several reasons. First, it minimizes energy waste by ensuring that the solar generation capacity is well-matched with the storage capacity of the on-site battery system. Second, it reduces the risk of overloading or damaging electrical equipment due to unmitigated excess solar production. Finally, by eliminating solar waste, we promote a more efficient and sustainable use of renewable energy resources, further enhancing the environmental benefits of the UAM network.

Three distinct vertiport networks are generated for each location and correspond to different levels of operational maturity: UML 1-2, UML 3-4, and UML 5-6 operations. These networks include 4, 20, and 40 vertiports respectively, with corresponding daily passenger volumes of 300, 1800, and 5000. The case study demonstrates that the UAM market share increases exponentially as the cost of UAM services decreases. UML 1-2 represents a 1% transportation market share, UML 3-4 corresponds to a 40% cost reduction, and UML 5-6 signifies an 80% cost reduction.

As discussed above, the GA is employed to minimize the total investment cost while adhering to the constraints and requirements specified in the problem formulation. One crucial aspect of the GA implementation is defining the termination criteria for the optimization process. In our case, we establish a termination criterion that combines multiple conditions.

The termination criteria according to the present disclosure were developed after numerous iterations, during which we identified the parameters that provided the best results in terms of solution results and the computational requirements for the algorithm to converge. Specifically, the termination criteria will stop the optimization process when the same optimal design is selected for 15 populations in a row, incorporating aspects of a Generation Number method, known to a person having ordinary skill in the art. This approach helps to prevent the GA from running indefinitely while ensuring that the solution has remained consistent across multiple generations.

Secondly, the termination criteria require that the rest of the population is within the tolerance of the selected network design, combining elements of fitness convergence and population convergence. This condition ensures that the fitness of the solutions has reached an acceptable level of consistency, and the population has converged, minimizing the likelihood of a suboptimal outcome.

This comprehensive approach to the termination criteria ensures that the optimization process can navigate the design space and identify a true global optimum. The developed criteria strike a balance between the need for accurate solutions and the necessity of feasible computation.

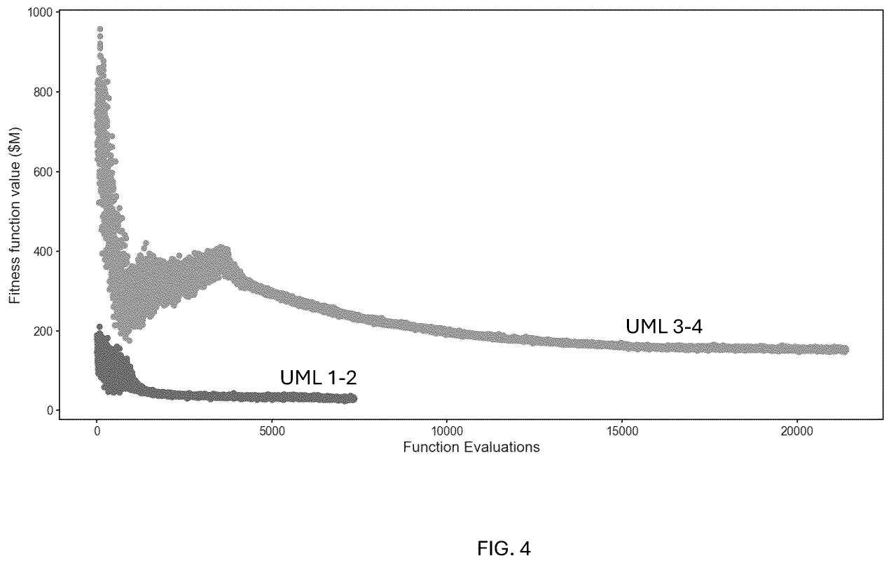

The convergence of the GA for the Urban Mobility Level UML 1-2 and UML 3-4 cases studies are shown in FIG. 4 which is a graph of fitness function value vs. function evaluations for UML 1-2 and UML 3-4 for the Los Angeles case study. As shown in FIG. 4, the solver tackles the optimization problem in a step-by-step manner, initially focusing on reducing the constraint violation to zero before moving on to minimize the fitness function. This approach ensures that the solution meets the necessary requirements and constraints set forth in the problem formulation.

For the UML 1-2 case, convergence is achieved after approximately 7,000 function evaluations, whereas the UML 3-4 case necessitated more than 21,000 function evaluations. This difference is caused by the increased number of decision variables of the UML 3-4 problem, which demands additional computational effort to explore the design space and identify the optimal solution. By illustrating the algorithm's ability to efficiently navigate the design space and converge to a suitable solution, we verify the effectiveness of the GA in addressing the UAM network sizing problem.

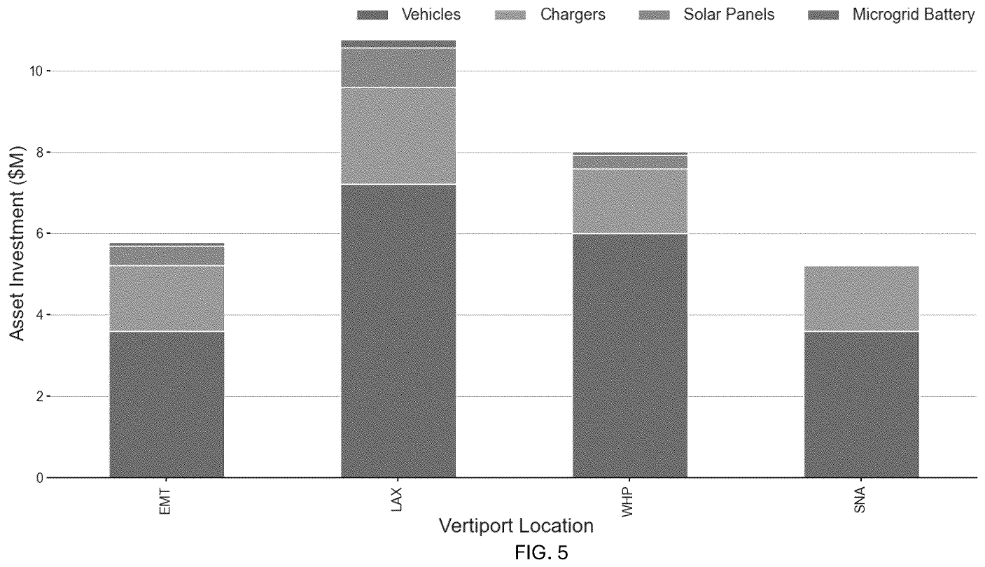

Referring to FIG. 5, a bar graph is provided for asset investment vs. vertiport location showing the optimization aspect with respect to locating vertiport. Accordingly, based on Los Angeles UML 1-2, a Hub-and-spoke transportation system emerges with LAX as a central investment hub. Specifically, FIG. 5 is a bar chart showing results of an optimized UAM network for a first urban setting (Los Angeles) and for a first maturity level (UML 1-2 with 4 vertiports)), in which an optimized output (i.e., number of vehicles, charger, solar panels, and batteries) are provided for each vertiport (based on the order: number of vehicles at the bottom, next number of chargers, next number of solar panels, and next number of batteries, where solar panels and batteries are coupled such that if there are no solar panels there are no batteries).

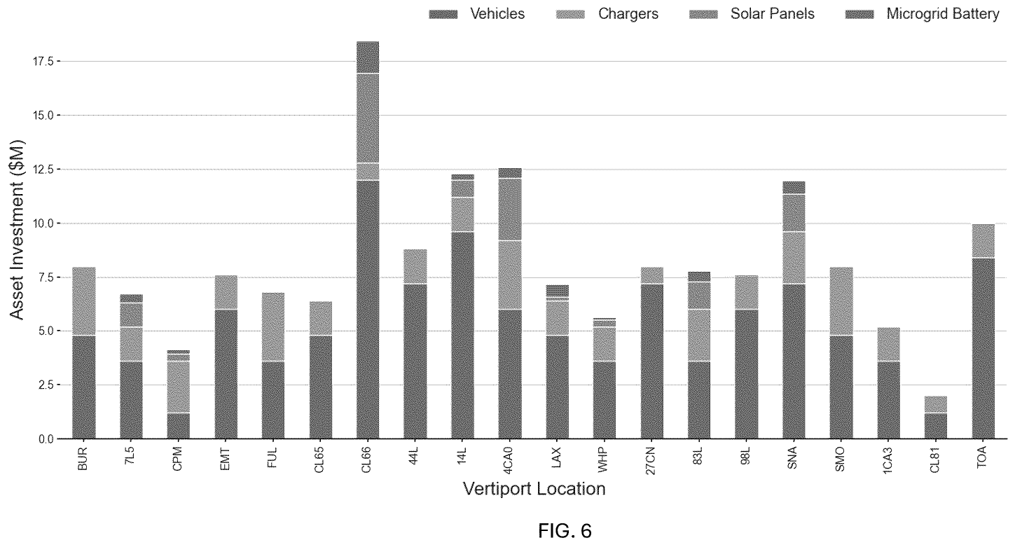

FIG. 6 is another bar chart similar to FIG. 5 showing results of an optimized UAM network for the first urban setting and for a second maturity level (UML 3-4 with 20 vertiports).

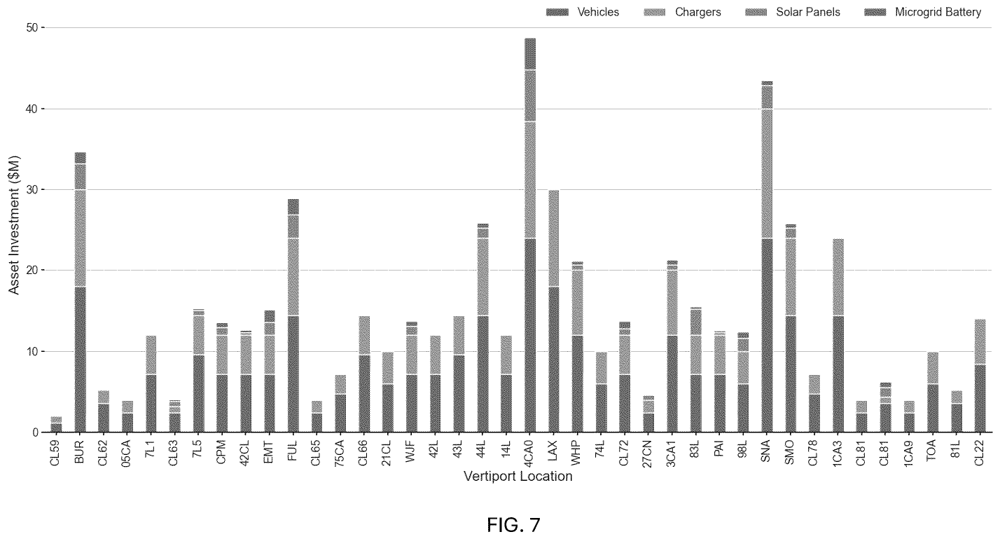

FIG. 7 is another bar chart similar to FIG. 5 showing results of an optimized UAM network for the first urban setting and for a third maturity level (UML 5-6 with 40 vertiports).

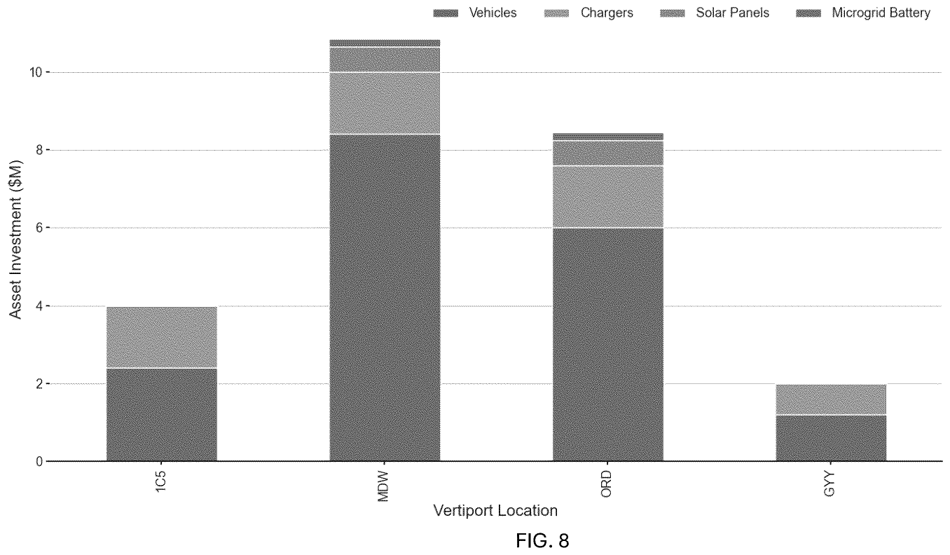

FIG. 8 is another bar chart similar to FIG. 5 showing results of an optimized UAM network for a second urban setting (Chicago) and for the first maturity level.

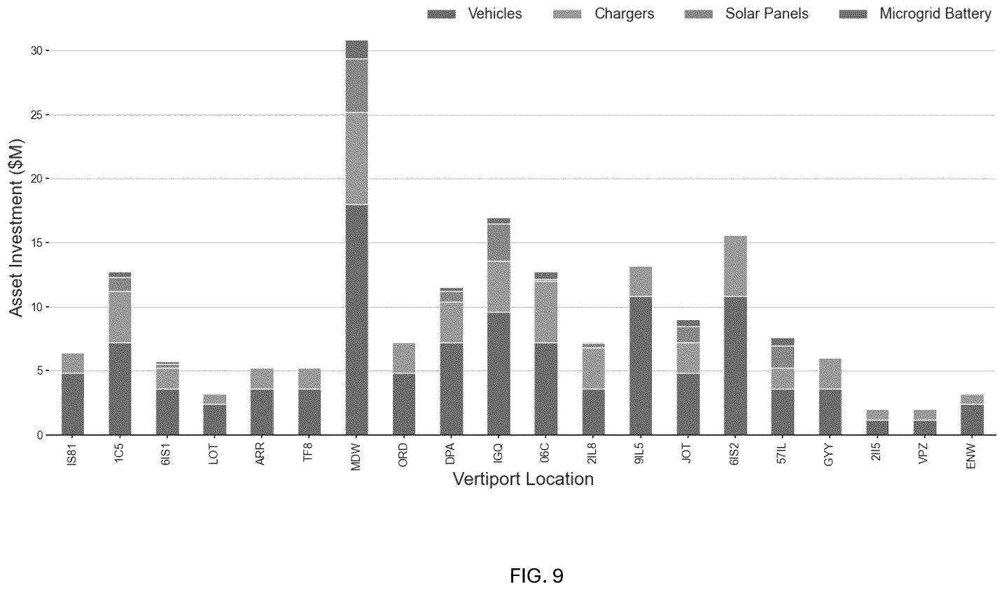

FIG. 9 is another bar chart similar to FIG. 5 showing results of an optimized UAM network for the second urban setting and for the second maturity level.

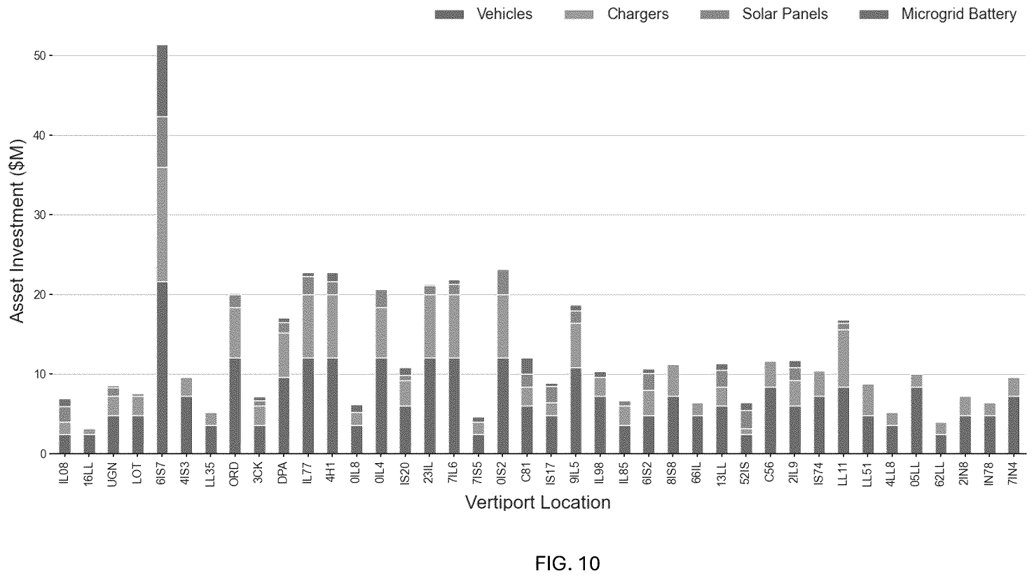

FIG. 10 is another bar chart similar to FIG. 5 showing results of an optimized UAM network for the second urban setting and for the third maturity level.

Further referring to FIG. 6, another bar graph is provided for asset investment vs. vertiport location showing the optimization aspect with respect to locating vertiport for UML 3-4. Accordingly, based on Los Angeles UML 3-4, increased microgrid investment highlights the importance of energy infrastructure. Thus, comparing the charts across different UML levels allows us to discern trends and patterns in the optimal vertiport networks. Vertiports in high-demand areas require greater investment due to increased throughput of UAM trips and charging events. These investment forecasts contribute to the development of the hub-and-spoke transportation model, emphasizing the significance of strategic planning and resource allocation in building efficient and sustainable UAM networks. Specifically, FIG. 5 clearly indicates that vehicle acquisition constitutes the largest investment in the UML 1-2 network, highlighting its importance in the overall cost structure of UAM operations. Additionally, three microgrids were sized across the vertiport networks, further illustrating the significance of energy infrastructure in supporting UAM growth. A notable outcome of the analysis is the development of a hub-and-spoke model, particularly in Los Angeles, with the Los Angeles International Airport (LAX) emerging as the most significant investment hub in terms of asset sizing. This result underscores the potential role of major airports in driving the expansion of UAM networks and facilitating efficient and sustainable UAM services.

Conversely, in the UML 3-4 scenario shown in FIG. 6, the optimization results show an increase in the number of microgrids, with a total of 9 microgrids sized across the vertiport networks. This indicates a higher level of operational maturity, as well as the growing importance of energy infrastructure to support the expansion of UAM services. As a result, a new hub emerges, referred to as “CL66.” This development suggests that as UAM operations evolve, additional vertiport hubs may arise to meet the increasing passenger demand and facilitate more efficient transportation connections. It is important to note the evident differences in the sizing requirements of each vertiport, which may be attributed to factors such as local energy constraints, passenger demand patterns, and the specific characteristics of each urban environment.

Referring to FIG. 7, which is another bar graph showing asset investment vs. vertiport location, a more advanced stage of UAM network development, with a total of 20 microgrids sized across the vertiport network is shown as part of UML 5-6. In this advanced scenario, the hub-and-spoke model becomes more pronounced, with key vertiport hubs such as 4CA0, SNA, and BUR emerging as the primary locations requiring significant investment. These findings highlight the dynamic nature of UAM network design and emphasize the need for a flexible and adaptable approach when planning and deploying UAM infrastructure.

Referring to FIGS. 8, 9, and 10 similar bar graphs as those shown in FIGS. 5, 6, and 7 are shown for the Chicago case study. Specifically, in the UML 1-2 scenario results shown in FIG. 8, the optimization results reveal that two microgrids were sized to support the vertiport network. The Midway International Airport (MDW) emerges as the location requiring the most investment, which can be attributed to its strategic position near the downtown city center and the associated high passenger demand. Similarly, FIG. 9 displays the results of the UML 3-4 for the Chicago case study. The optimization results reveal a more mature UAM network, with a total of 9 microgrids sized to support the vertiport infrastructure. Among the vertiports, Midway International Airport (MDW) stands out as the most prominent hub. Similarly, the UML 5-6 results found in FIG. 10 observe a further expansion of the UAM network, with a total of 26 microgrids sized to support the vertiport infrastructure. This number surpasses the microgrid count in the Los Angeles UML 5-6 scenario, indicating a higher degree of network complexity and energy infrastructure requirements in the Chicago area.

A striking result in this scenario is the emergence of 6IS7 as a major hub, requiring an investment that is significantly more than the next highest investment. The prominence of 6IS7 can be attributed to its strategic location near the heavily centralized commuter center in downtown Chicago. As the demand for UAM services grows, this hub is well-positioned to provide convenient and efficient transportation options to a large number of passengers.

These two case studies, indicate that both cities exhibit unique characteristics that influence the structure and investment requirements of their respective UAM systems.

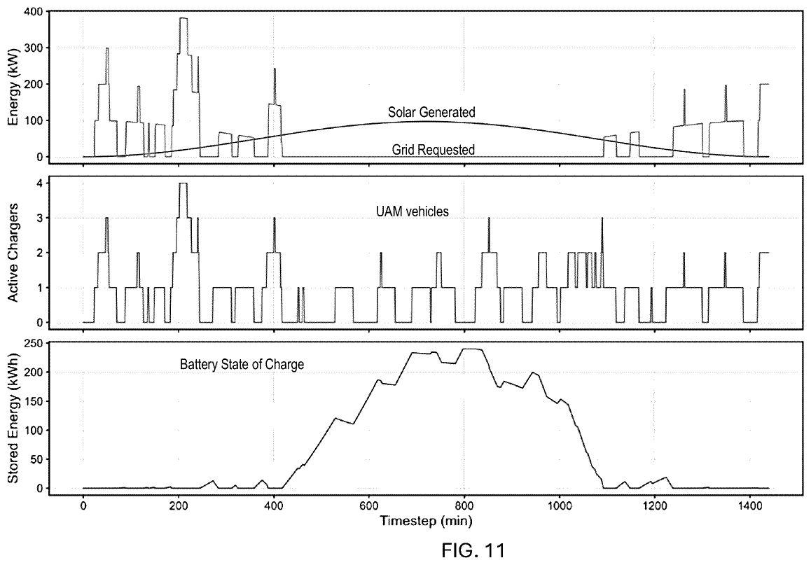

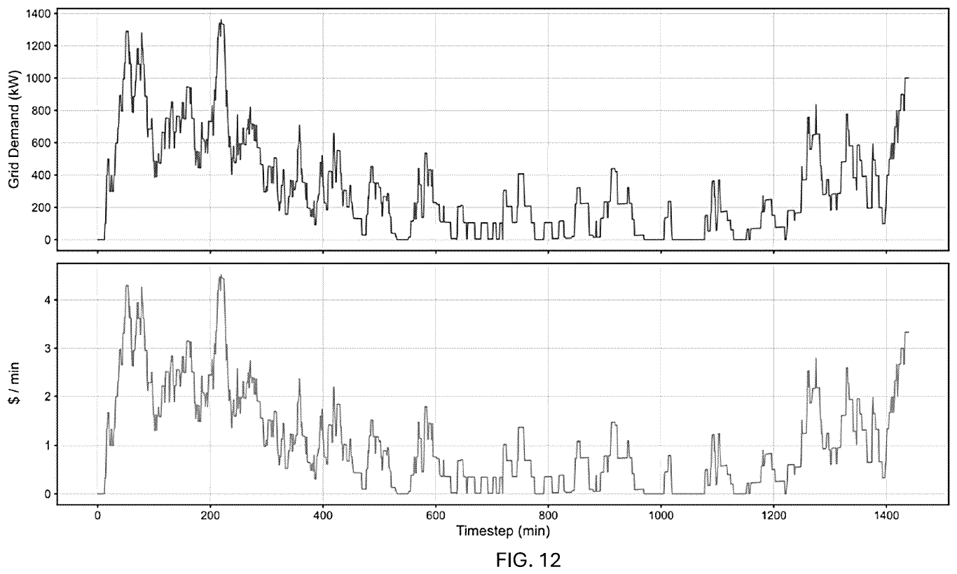

The output of the genetic algorithm is shown in FIGS. 11 and 12. FIG. 11 provides three graphs of i) energy in kW (for both solar panels and power requested from the grid); ii) number of chargers; and iii) stored energy (i.e., state of charge of all batteries), the graphs are for one of the vertiports in an urban setting, and vs. timestep defining length of a day. FIG. 12 provides an average of grid demand and cost for all vertiport in the urban setting of FIG. 11.

Those having ordinary skill in the art will recognize that numerous modifications can be made to the specific implementations described above. The implementations should not be limited to the particular limitations described. Other implementations may be possible.

1. A method of optimizing an Urban air mobility (UAM) network, comprising:
receiving a predetermined vertiport network, wherein each vertiport in the predetermined network is represented by a plurality of parameters;
receiving a customer demand schedule representing customer demand for each said vertiport;
using a model simulating the UAM network thus outputting a solution for the plurality of parameters;
inputting the output of the simulation to a genetic algorithm (GA);
optimizing the GA to thereby generate an optimized solution based on minimizing a mathematical function associated with the plurality of parameters until a predetermined termination criteria associated with network size is reached; and
outputting the optimized solution.

2. The method of claim 1, wherein the plurality of parameters include number of vehicles, number of chargers, number of solar panels, and number of batteries for each of the vertiports.

3. The method of claim 1, wherein the optimized solution is based on minimizing energy requirements from a local grid.

4. The method of claim 1, wherein the optimized solution is based on minimizing charges in each vertiport.

5. The method of claim 1, wherein the termination criteria is based on same optimized solution recursively generated for a predetermined number of times.

6. The method of claim 5, wherein the predetermined number of times is at least 20.

7. The method of claim 5, wherein the predetermined number of times is at least 15.

8. The method of claim 5, wherein the predetermined number of times is at least 10.

9. The method of claim 2, wherein the mathematical function is:
$$minimize {\sum }_{v ∈ N} {C}_{u} {X}_{v u} + {C}_{c} {X}_{v c} + {C}_{s} {X}_{v s} + {C}_{b} {X}_{v b} ,$$
where Cᵤ represents unit cost for Xᵥᵤ vehicles,
C_{c} represents unit cost for X_{vc} chargers,
Cₛ represents unit cost for Xᵥₛ solar panels,
C_{b} represents unit cost for X_{vb} batteries,
v represents each vertiport in the network of vertiports.

10. The method of claim 9, wherein variables in the mathematical function are constrained based on:
$${PD}_{v} \leq P {D}_{max} ( {∀}_{v} ∈ N ) ;$$
$$G {U}_{v} \leq G {U}_{max} ( {∀}_{v} ∈ N ) ;$$
$$G {M}_{v} \leq G {M}_{max} ( {∀}_{v} ∈ N ) ;$$
$$S {W}_{v} \leq S {W}_{max} ( {∀}_{v} ∈ N ) ;$$
$${X}_{u v} , {X}_{c v} , {X}_{s v} , {X}_{b v} \geq 0 ( {∀}_{v} ∈ N ) ;$$
$$and {X}_{u v} , {X}_{c v} , {X}_{s v} , {X}_{b v} ∈ Z ( {∀}_{v} ∈ N ) ,$$
where PDᵥ represents number of vehicles in each vertiport,
PDₘₐₓ represents maximum number of vehicles;
GUᵥ represents grid usage;
GUₘₐₓ represents maximum grid usage;
GMᵥ represents grid demand peak;
GMₘₐₓ represents maximum grid demand peak;
SWᵥ represents wasted solar power due to full batteries; and
SWₘₐₓ represents maximum wasted solar power due to full batteries.

11. A system of optimizing an Urban air mobility (UAM) network, comprising:
a UAM network, comprising:
a vertiport network of a plurality of vertiports, each vertiport defined by a plurality of parameters,
an electric grid coupled to the vertiport network;
a processor executing instructions on a non-transitory memory, the processor configured to:
receive a predetermined vertiport network, wherein each vertiport in the predetermined network is represented by the plurality of parameters;
receive a customer demand schedule representing customer demand for each said vertiport;
simulate the UAM network using a model thus outputting a solution for the plurality of parameters;
input the output of the simulation to a genetic algorithm (GA); and
optimize the GA to thereby generate an optimized solution based on minimizing a mathematical function associated with the plurality of parameters until a predetermined termination criteria associated with network size is reached; and
output the optimized solution.

12. The system of claim 11, wherein the plurality of parameters include number of vehicles, number of chargers, number of solar panels, and number of batteries for each of the vertiports.

13. The system of claim 11, wherein the optimized solution is based on minimizing energy requirements from a local grid.

14. The system of claim 11, wherein the optimized solution is based on minimizing charges in each vertiport.

15. The system of claim 11, wherein the termination criteria is based on same optimized solution recursively generated for a predetermined number of times.

16. The system of claim 15, wherein the predetermined number of times is at least 20.

17. The system of claim 15, wherein the predetermined number of times is at least 15.

18. The system of claim 15, wherein the predetermined number of times is at least 10.

19. The system of claim 12, wherein the mathematical function is:
$$minimize {\sum }_{v ∈ N} {C}_{u} {X}_{v u} + {C}_{c} {X}_{v c} + {C}_{s} {X}_{v s} + {C}_{b} {X}_{v b} ,$$
where Cᵤ represents unit cost for Xᵥᵤ vehicles,
C_{c} represents unit cost for X_{vc} chargers,
Cₛ represents unit cost for Xᵥₛ solar panels,
C_{b} represents unit cost for X_{vb} batteries,
v represents each vertiport in the network of vertiports.

20. The system of claim 19, wherein variables in the mathematical function are constrained based on:
$${PD}_{v} \leq P {D}_{max} ( {∀}_{v} ∈ N ) ;$$
$$G {U}_{v} \leq G {U}_{max} ( {∀}_{v} ∈ N ) ;$$
$$G {M}_{v} \leq G {M}_{max} ( {∀}_{v} ∈ N ) ;$$
$$S {W}_{v} \leq S {W}_{max} ( {∀}_{v} ∈ N ) ;$$
$${X}_{u v} , {X}_{c v} , {X}_{s v} , {X}_{b v} \geq 0 ( {∀}_{v} ∈ N ) ;$$
$$and {X}_{u v} , {X}_{c v} , {X}_{s v} , {X}_{b v} ∈ Z ( {∀}_{v} ∈ N ) ,$$
where PDᵥ represents number of vehicles in each vertiport,
PDₘₐₓ represents maximum number of vehicles;
GUᵥ represents grid usage;
GUₘₐₓ represents maximum grid usage;
GMᵥ represents grid demand peak;
GMₘₐₓ represents maximum grid demand peak;
SWᵥ represents wasted solar power due to full batteries; and
SWₘₐₓ represents maximum wasted solar power due to full batteries.
